(19) United States
(12) Patent Application Publication
(10) Pub. No.: US 2025/0210104 A1
(43) Pub. Date: Jun. 26, 2025

(54) MEMORY DEVICE PERFORMING IN-MEMORY COMPUTING AND OPERATING METHOD THEREOF

(71) Applicant: SEOUL NATIONAL UNIVERSITY R&DB FOUNDATION, Seoul (KR)

(72) Inventors: Jae-Joon KIM, Seoul (KR); Eunhwan KIM, Pohang-si (KR)

(21) Appl. No.: 18/976,504

(22) Filed: Dec. 11, 2024

(30) Foreign Application Priority Data
Dec. 20, 2023 (KR) 10-2023-0186857
Apr. 19, 2024 (KR) 10-2024-0052550

(51) Int. Cl. G11C 11/412; G11C 5/14; G11C 11/419

(52) U.S. Cl. CPC G11C 11/412; G11C 5/148; G11C 11/419

(57) ABSTRACT

A memory device includes a plurality of memory cells, each being configured to perform in-memory computing; a storage unit storing data; and an operation circuit including a first capacitor and a second capacitor and configured to adjust a voltage charged to the first capacitor and a voltage charged to the second capacitor according to input data and storage data stored in the storage unit.

### CROSS-REFERENCE TO RELATED APPLICATION

This application claims the benefit under 35 USC 119(a) of Korean Patent Application Nos. 10-2024-0052550 filed on Apr. 19, 2024 and 10-2023-0186857 filed on Dec. 20, 2023 in the Korean Intellectual Property Office, the entire disclosures of which are incorporated herein by reference for all purposes.

### BACKGROUND

### 1. Field

The present disclosure relates to a memory device performing in-memory computing and an operating method thereof.

### 2. Description of the Related Art

Computing in memory (CIM) is also called in-memory computing (IMC) or processing in memory (PIM), and is technology for enabling a memory device to perform computational functions in addition to data storage functions, and has been widely studied recently as a technology for implementing artificial intelligence (AI) semiconductors.

FIG. 1 illustrates a memory device that performs general in-memory computing.

As illustrated in FIG. 1, the memory device includes a plurality of memory cells that simulate synapses, and may include a digital-to-analog converter (DAC), an analog-to-digital converter (ADC), or so on as a peripheral circuit. In particular, IMC memory cells receive analog values corresponding to multi-bit digital values as inputs through a digital-to-analog converter (DAC). Because DACs are provided for each column, there is a problem that the DACs consume a lot of energy and also occupy a large area. In addition, improvement is required in that a separate DAC module has to be provided outside each memory cell.

The present disclosure reduces energy consumption and an area increase by incorporating a DAC into a memory cell.

A prior patent document related to this includes Korean Patent Publication No. 2023-0078218 (Title of invention: Memory device having local computing cell based on computing-in-memory).

### SUMMARY

The present disclosure provides a memory device that may perform a DAC operation and a computational operation within a memory cell, and an operating method of the memory device.

However, technical objects to be achieved by the present embodiments are not limited to the technical objects described above, and there may be other technical objects.

According to an aspect of the present disclosure, a memory device includes a plurality of memory cells, each of the plurality of memory cells performs in-memory computing and includes a storage unit storing data and an operation circuit. In this case, the operation circuit includes a first capacitor and a second capacitor and adjusts a voltage charged to the first capacitor and a voltage charged to the second capacitor according to input data and storage data stored in the storage unit.

According to another aspect of the present disclosure, an operating method of a memory device including a plurality of memory cells, each of which performs in-memory computing and includes a storage unit for storing data and an operation circuit adjusting a voltage charged to a first capacitor or a second capacitor according to input data and storage data stored in the storage unit. The operating method of the memory device includes a precharging step of charging the first capacitor and the second capacitor with a power supply voltage; and a data application step of adjusting a voltage charged to the first capacitor or the second capacitor according to the input data and the storage data.

According to the present disclosure, a DAC operation for converting digital data into analog data and multiplication may be performed by each memory cell, and thus, an area of the memory device that performs in-memory computing may be reduced, and energy consumption of the memory device may also be reduced.

### BRIEF DESCRIPTION OF THE DRAWINGS

FIG. 1 illustrates a memory device that performs general in-memory computing.

FIG. 2 illustrates a memory device according to an embodiment of the present disclosure.

FIG. 3 illustrates a detailed configuration of a memory cell according to an embodiment of the present disclosure.

FIG. 4 illustrates a configuration in which a plurality of memory cells are combined with each other, according to an embodiment of the present disclosure.

FIGS. 5 and 6 are diagrams illustrating operations of a memory cell according to an embodiment of the present disclosure.

FIG. 7 illustrates a detailed configuration of a memory cell according to another embodiment of the present disclosure.

FIG. 8 is a diagram illustrating an operation of a memory cell according to another embodiment of the present disclosure.

FIG. 9 is a flowchart illustrating an operating method of a memory device, according to an embodiment of the present disclosure.

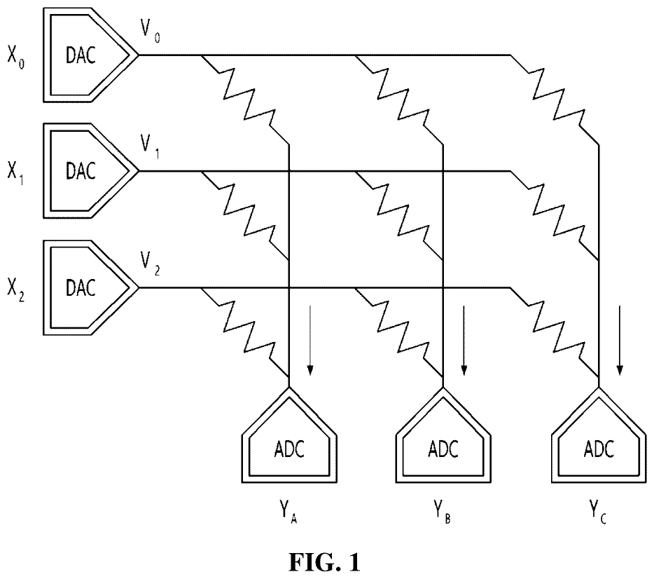

### DETAILED DESCRIPTION

Hereinafter, embodiments of the present disclosure will be described in detail with reference to the attached drawings such that those skilled in the art to which the present disclosure belongs may easily practice the present disclosure. However, the present disclosure may be implemented in various different forms and is not limited to the embodiments described herein. In addition, in order to clearly describe the present disclosure in the drawings, parts that are not related to the description are omitted, and similar components are given similar reference numerals throughout the specification.

In the entire specification of the present disclosure, when a component is described to be “connected” to another component, this includes not only a case where the component is “directly connected” to another component but also a case where the component is “electrically connected” to another component with another element therebetween. In addition, when it is described that a portion “includes” a certain component, this means that the portion may further include another component without excluding another component unless otherwise stated.

In the present disclosure, a “portion” includes a unit realized by hardware, a unit realized by software, and a unit realized by using both. In addition, one unit may be realized by using two or more pieces of hardware, and two or more units may be realized by using one piece of hardware. Meanwhile, a “˜portion” is not limited to software or hardware, and a “˜portion” may be configured to be included in an addressable storage medium or may be configured to reproduce one or more processors. Therefore, in one example, “˜portion” refers to components, such as software components, object-oriented software components, class components, and task components, and includes processes, functions, properties, and procedures, subroutines, segments of program code, drivers, firmware, microcode, circuits, data, databases, data structures, tables, arrays, and variables. The functions provided within the components and “portions” may be combined into a smaller number of components and “portions” or may be further separated into additional components and “portions”. Additionally, components and “portions” may be implemented to regenerate one or more central processing units (CPUs) included in a device or security multimedia card.

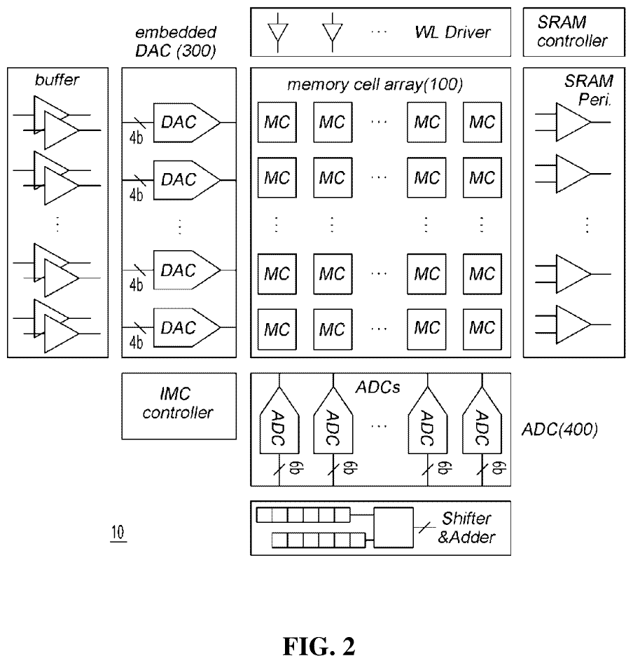

FIG. 2 illustrates a memory device 10 according to an embodiment of the present disclosure.

The memory device 10 includes a memory cell array 100 in which a plurality of memory cells performing in-memory computing are arranged in an array form, an embedded digital-to-analog converter (DAC) 300 that converts input data received from a buffer into an analog signal and provides analog signal to a memory cell MC and is implemented in a form that is built into each memory cell, and an analog-to-digital converter (ADC) 400 that receives the analog signal output from the memory cell array 100 and converts the analog signal into a digital signal. In addition, the memory device 10 may further include peripheral circuits, such as a static random access memory (SRAM) controller that controls an operation of SRAM included in each memory cell, an in-memory computing (IMC) controller that controls an operation of each memory cell MC that performs in-memory computing, and a shifter and adder. In this case, the input data may be input activation data of each layer constituting a deep neural network or so on, and multiplication of the input data and storage data may correspond to multiplication of an input activation and weight data.

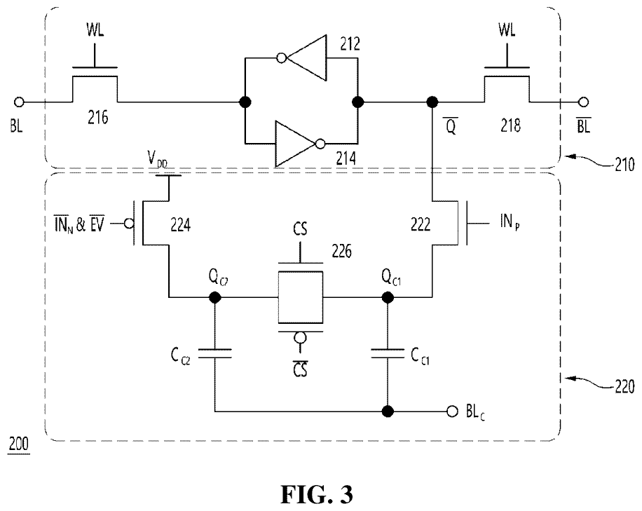

FIG. 3 illustrates a detailed configuration of a memory cell 200 according to an embodiment of the present disclosure.

The memory cell 200 of the present disclosure includes a storage unit 210 that stores storage data and an operation circuit 220. The operation circuit 220 includes a first capacitor C_{C1} and a second capacitor C_{C2}, and adjusts a voltage charged to the first capacitor C_{C1} or the second capacitor C_{C2} according to the input data and storage data. In addition, the operation circuit 220 converts the input data into an analog voltage and performs multiplication of the storage data stored in the storage unit 210 and the input data. In addition, the operation circuit 220 includes the first capacitor C_{C1} and the second capacitor C_{C2} that share a charge capacity according to a charge sharing signal as a DAC that converts multi-bit input data into an analog voltage.

The storage unit 210 operates according to an SRAM structure and includes a first inverter 212, a second inverter 214, a first switching element 216, and a second switching element 218. The storage data stored in the storage unit 210 is transmitted to the operation circuit 220. In this case, the storage data may be weight data constituting an artificial intelligence model or a deep neural network model of which learning is completed.

An output terminal of the first inverter 212 is connected to an input terminal of the second inverter 214, and an output terminal of the second inverter 214 is connected to an input terminal of the first inverter 212. Because each the first and second inverters 212 and 214 includes two switching elements, the storage unit 210 includes a total of six switching elements. The first switching element 216 has one terminal connected to a connection node between the output terminal of the first inverter 212 and the input terminal of the second inverter 214, and has the other terminal connected to a bit line BL, and has a gate to which a word line signal is applied, thereby being switched according to the word line signal. The second switching element 218 has one terminal connected to a connection node /Q between the input terminal of the first inverter 212 and the output terminal of the second inverter 214, and has the other terminal connected to a bit line/BL, and has a gate to which a word line signal is applied, thereby being switched according to the word line signal. In particular, a value of the connection node /Q, to which the second switching element 218, an input terminal of the first inverter 212, and the output terminal of the second inverter 214 are connected, is transmitted to the operation circuit 220. In this case, the connection node /Q functions as an output node from which the storage unit 210 outputs the stored data.

The operation circuit 220 causes a third switching element 226 to selectively connect one terminal of the first capacitor C_{C1} to one terminal of the second capacitor C_{C2}, and causes the other terminal of the first capacitor C_{C1} and the other terminal of the second capacitor C_{C2} to an output terminal BL_{c}. In addition, the first capacitor C_{C1} and the second capacitor C_{C2} are precharged to a high voltage, and when high-level input data is input, a charging state of the first capacitor C_{C1} changes according to the storage data, and when low-level input data is input, the second capacitor C_{C2} is charged to a high voltage, and the third switching element 226 is turned on according to a charge sharing signal to connect the first capacitor C_{C1} to the second capacitor C_{C2}, causing an average value of charging voltages is charged in each capacitor.

The operation circuit 220 includes a first switching element 222 which is switched by a high-level bit of input data in a multi-bit format, has one terminal connected to the output node /Q of the storage unit 210, and has the other terminal connected to one terminal of the first capacitor C_{C1}, a second switching element 224 which is switched by a low-level bit of the input data in a multi-bit format, has one terminal connected to a power supply voltage, and has the other terminal connected to one terminal of the second capacitor C_{C2}, and the third switching element 226 which is connected between one terminal of the first capacitor C_{C1} and one terminal of the second capacitor C_{C2} and is switched by a charge sharing signal.

For more specific configuration, the operation circuit 220 includes the first switching element 222 which is switched by first input data IN_{P} and has one terminal connected to the output node /Q of the storage unit 210 and transmits the stored data to the other terminal Q_{C1}, the second switching element 224 which is switched by inverted second input data /IN_{N} or an inverted control signal /EV and has one terminal connected to a power supply voltage VDD and transmits the power supply voltage VDD to the other terminal Q_{C2}, the first capacitor C_{C1} which has one terminal connected to the other terminal Q_{C1} of the first switching element 222, the second capacitor C_{C2} which has one terminal connected to the other terminal Q_{C2} of the second switching element 224, and the third switching element 226 which is connected between one terminal of the first capacitor C_{C1} and one terminal of the second capacitor C_{C2} and is switched by a charge sharing signal CS. In addition, the other terminal of the first capacitor C_{C1} and the other terminal of the second capacitor C_{C2} are commonly connected to the output terminal BL_{c}.

Through the configuration, the operation circuit 220 performs a DAC operation for converting input data into an analog voltage and multiplication of the stored data and the input data. In addition, an NMOS transistor may be used as the first switching element 222, a PMOS transistor may be used as the second switching element 224, and a transmission gate may be used as the third switching element 226, but the present disclosure is not limited thereto and the first, second, and third switching elements 222, 224, and 226 may be modified to other elements.

A DAC function of the operation circuit 220 is performed as follows. That is, according to pulse signals applied to the first switching element 222 and the second switching element 224, a high level bit and a low level bit of multi-bit input data are respectively applied to the first switching element 222 and the second switching element 224. In addition, according to the charge sharing signal CS input in synchronization with an application time of a clock pulse signal, charging capacities of the first capacitor C_{C1} and the second capacitor C_{C2} are shared to output analog voltages corresponding to the input data.

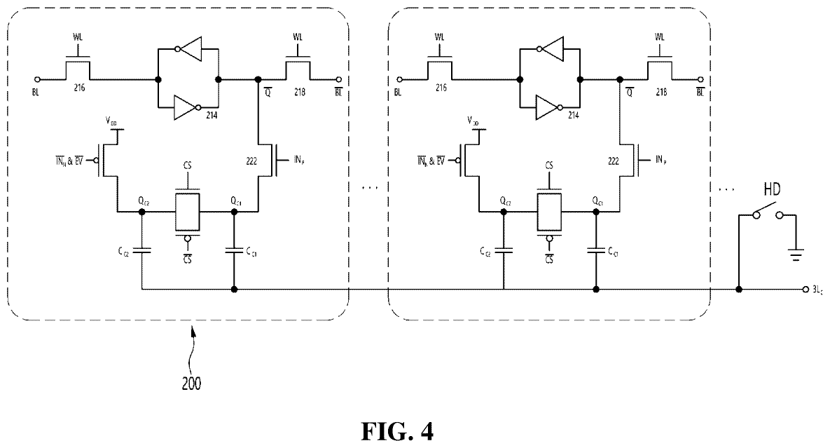

FIG. 4 illustrates a configuration in which a plurality of memory cells are combined according to an embodiment of the present disclosure.

As illustrated in FIG. 4, a plurality of memory cells (200) may be connected to one row, and output terminals BLc of the operation circuits 220 of respective memory cells 200 are commonly connected to each other. In addition, a holding switching element that is activated by a hold signal HD and selectively connects the output terminal BLc to a ground may be combined to the memory cell 200.

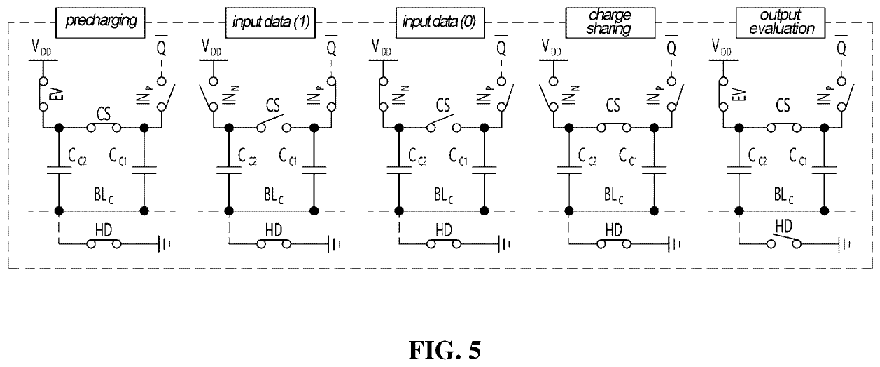

FIGS. 5 to 8 are diagrams illustrating an operation of a memory cell according to an embodiment of the present disclosure.

For the sake of simplicity of description, FIG. 5 illustrates only an operation of the operation circuit 220 in the memory cell 200.

First, in a precharging step, the power supply voltage VDD is applied to the first capacitor C_{C1} and the second capacitor C_{C2}. To this end, a control signal EV is applied to the second switching element 224 to turn on the second switching element 224, and the charge sharing signal CS is also applied to turn on the third switching element 226. Accordingly, the power supply voltage VDD is applied to the first capacitor C_{C1} and the second capacitor C_{C2}, such that the first capacitor C_{C1} and the second capacitor C_{C2} are charged to high voltages.

Next, a data application mode for applying the input data and the storage data to each capacitor is performed. Among the input data in a multi-bit format, a high level bit is applied as first input data IN_{P}, and a low level bit is applied as second input data IN_{N}. To this end, the first input data IN_{P} and the inverted second input data /IN_{N} are respectively applied to a gate of the first switching element 222 and a gate of the second switching element 224. In addition, when the high level bit among the input data is received, the first input data IN_{P} is set to a high level 1,and when the low level bit is received, the second input data INN is set to a low level 0. In this case, the first switching element 222 is an NMOS transistor, and the second switching element 224 is a PMOS transistor, and accordingly, inverted second input data /IN_{N} is applied to a gate of the second switching element 224. In addition, while the input data is applied to each switching element, the charge sharing signal CS is blocked, and accordingly, the input data is separately applied to the respective capacitors.

Thereafter, in a charge sharing mode, input data application is blocked, and the charge sharing signal CS is applied for a certain period of time to cause electric charges to be shared with each capacitor. In addition, when the input data is n-bit data, input data application and charge sharing are repeatedly performed by n times.

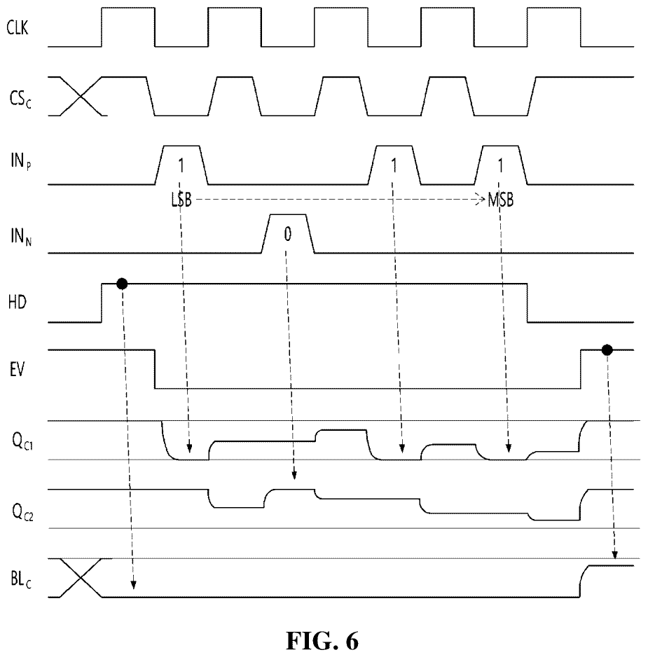

FIG. 6 illustrates an example where the input data is ‘1101’. A least significant bit (LSB) is input first, and after respective pieces of input data are applied sequentially, a most significant bit (MSB) is input last.

First, as ‘1’ is input as the LSB, the first input data IN_{P} of a high level is applied to the first switching element 222, and the second input data IN_{N} of a low level is applied to the second switching element 224. As the first switching element 222 is turned on and the second switching element 224 is turned off, a charging state of the first capacitor C_{C1} charged to a high voltage in the precharging step is changed by the storage data stored in the storage unit 210.

That is, when the storage data ‘1’ is stored in the storage unit 210 (an output of the first inverter 212 is 1), the output node /Q decreases to a low level GND, and accordingly, the first capacitor C_{C1} is discharged, as illustrated in FIG. 6. In contrast to this, when the storage data ‘0’ is stored in the storage unit 210 (an output of the second inverter 214 is 1), the output node /Q increases to a high level VDD, and accordingly, the first capacitor C_{C1} may maintain a high voltage charging state. In addition, after the LSB of ‘1’ is input, when the charge sharing signal CS is applied, the first and second switching elements 222 and 224 are turned off, and each of the first capacitor C_{C1} and the second capacitor C_{C2} has an average value (0.5 VDD) of charged electric charges due to charge sharing. As illustrated in FIG. 6, a voltage charging state changes to an average state of the discharged first capacitor C_{C1} and the high-voltage charged second capacitor C_{C2}.

Next, as ‘0’ is input as a third bit, the first input data IN_{P} at a low level is applied to the first switching element 222, and the second input data IN_{N} at a high level is applied to the second switching element 224. Because the second input data IN_{N} at a high level is inverted and applied to the second switching element 224, the second switching element 224 is turned on and the first switching element 222 is turned off. Accordingly, the power supply voltage VDD is applied to the second capacitor C_{C2}, and thereby, the second capacitor C_{C2} is charged to a high level, and the first capacitor C_{C1} maintains the previous state. Thereafter, when the charge sharing signal CS is applied, the first and second switching elements 222 and 224 are turned off, and each of the first capacitor C_{C1} and the second capacitor C_{C2} has an average value of the electric charges charged by the charge sharing. As ‘0’ is applied as the third bit and the second capacitor C_{C2} is charged to a high level, it can be seen that a charging voltage (0.75 VDD) of each of the first capacitor C_{C1} and the second capacitor C_{C2} increases compared to the charging voltage at the time of the previous charge sharing.

Next, as ‘1’ is input as the second bit, the first input data IN_{P} at a high level is applied to the first switching element 222, and the second input data IN_{N} at a low level is applied to the second switching element 224. As described above, as the first switching element 222 is turned on, a charging state of the first capacitor C_{C1} changes according to the storage data stored in the storage unit 210. Thereafter, when the charge sharing signal CS is applied, each of the first capacitor C_{C1} and the second capacitor C_{C2} has an average value of the charged electric charges.

Next, as ‘1’ is input as the MSB, the first input data IN_{P} at a high level is applied to the first switching element 222, and the second input data IN_{N} at a low level is applied to the second switching element 224. As the first switching element 222 is turned on, a charging state of the first capacitor C_{C1} is changed by the storage data stored in the storage unit 210. Thereafter, when the charge sharing signal CS is applied, each of the first capacitor C_{C1} and the second capacitor C_{C2} has an average value of the charged electric charges, and the average value is determined as a final charge voltage Vcs,final.

Finally, in an output evaluation step, the inverted control signal /EV is applied to the second switching element 224, the first switching element 222 is maintained in a turn-off state, and a holding signal HD applied to the holding switching element is blocked. Accordingly, a voltage of one terminal of the second capacitor C_{C2} increases to a power supply voltage level, and the other terminal of the second capacitor C_{C2}, that is, the output terminal BLc, outputs an evaluation voltage. In this case, the evaluation voltage becomes VDD-Vcs,final (final charge voltage) by capacitor coupling. That is, immediately before an output evaluation step, each of one terminal of the first capacitor C_{C1} and one terminal of the second capacitor C_{C2} has the average value Vcs,final of the charged electric charges, and as a power supply voltage is applied to one terminal of the first capacitor C_{C2} and one terminal of the second capacitor C_{C2} during the output evaluation step, each of voltages of the other terminal of the first capacitor C_{C1} and the other terminal of the second capacitor C_{C2} is set to VDD-Vcs,final (final charge voltage).

In this way, the operation circuit 220 adjusts voltages of the output terminals of the first and second capacitors C_{C1} and C_{C2} according to the input data input through gates of the first and second switching elements 222 and 224 and the storage data stored in the storage unit 210. That is, the operation circuit 220 may perform a NAND operation on the input data and the storage data. In addition, it can be seen that the operation circuit 220 also performs a DAC function that converts digital input data input through gates of the first and second switching elements 222 and 224 into an analog voltage through charging voltages of the first and second capacitors C_{C1} and C_{C2}.

In the conventional technology, a voltage is applied to a source or drain of a switching element to transmit an analog voltage value to each capacitor, but in the present disclosure, input data is applied as a gate signal of a switching element, and thus, the present disclosure is effective for small and fast signal transmission.

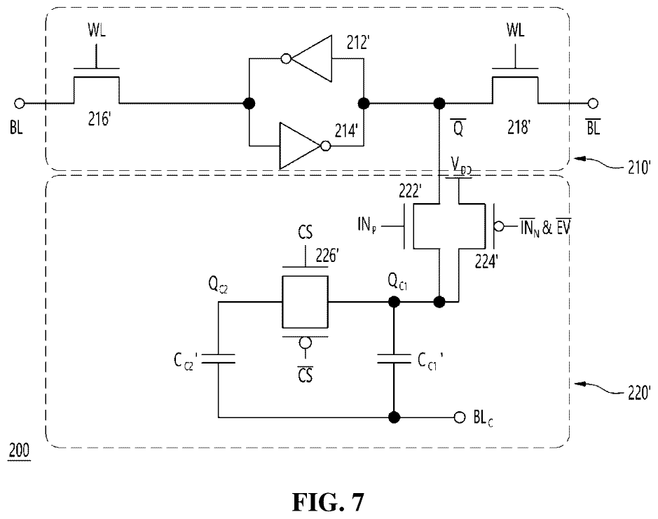

FIG. 7 illustrates a detailed configuration of a memory cell according to another embodiment of the present disclosure.

A configuration of a storage unit 210′ is the same as the storage unit 210 of FIG. 3, and accordingly, detailed description thereof is omitted.

A configuration of the operation circuit 220′ also generally corresponds to the operation circuit 220 of FIG. 3, but there is a difference in a configuration of the second switching element 224′. The second switching element 224′ has a structure in which the other terminal of the second switching element 224′ is connected to one terminal of a first capacitor C₁′.

More specifically, the operation circuit 220′ includes a first switching element 222′ that is switched by first input data INp and has one terminal connected to an output node /Q of the storage unit 210′ and transmits the stored data to the other terminal QC1, the second switching element 224′ that is switched by second input data IN_{N} or a control signal EV and has one terminal connected to a power supply voltage VDD and transmits the power supply voltage VDD to the other terminal QC1, the first capacitor C_{C1}′ that has one terminal connected to the other terminal QC1 of the first switching element 222′ and the second switching element 224′ and has the other terminal connected to an output terminal BLc, a second capacitor C_{C2}′ that has the other terminal connected to the output terminal BLc, and a third switching element 226′ connected between one terminal of the first capacitor C_{C1}′ and one terminal of the second capacitor C_{C2}′ and switched by a charge sharing signal CS.

A detailed operation thereof also generally corresponds to the operation of FIG. 3.

First, in a precharging step, initialization for applying the power supply voltage VDD to the first capacitor C_{C1}′ and the second capacitor C_{C2}′ is performed. To this end, the control signal EV is applied to the second switching element 224 to turn on the second switching element 224′, and the charge sharing signal CS is also applied to turn on the third switching element 226′. Accordingly, the power supply voltage VDD is applied to the first capacitor C_{C1} and the second capacitor C_{C2}.

Next, in a data application mode, the first input data IN_{P} and the inverted second input data /IN_{N} are respectively applied to gates of the first switching element 222′ and the second switching element 224′. Then, while the input data is applied to the first and second switching elements 222′ and 224′, the charge sharing signal CS is blocked such that the input data is separately applied to the first and second capacitors C_{C1} and C_{C2}. Thereafter, the application of the input data is blocked, and the charge sharing signal CS is applied for a certain period of time such that electric charges are shared between respective capacitors.

Meanwhile, when the first input data IN_{P} is at a high level, the first switching element 222′ is turned on, and accordingly, storage data stored in the storage unit 210 may be transmitted to the capacitor through the output node /Q and the first switching element 222′.

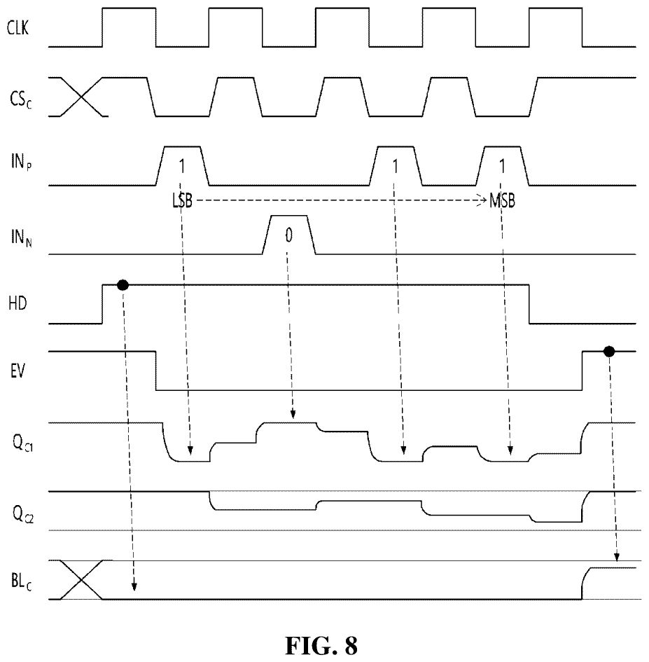

Referring to FIG. 8 for a detailed operation, when ‘1’ is input as an LSB, the first switching element 222′ is turned on and the second switching element 224′ is turned off, and accordingly, a charging state of the first capacitor C_{C1}′ charged to a high voltage during a precharging step is changed by the storage data stored in the storage unit 210. That is, when the storage data ‘1’ is stored in the storage unit 210, the output node /Q decreases to a low level GND, and accordingly, the first capacitor C_{C1}′ is discharged. In contrast to this, when the storage data ‘0’ is stored in the storage unit 210, the output node /Q increases to a high level VDD, and accordingly, the first capacitor C_{C1}′ may maintain a high-voltage charging state. In addition, when the charge sharing signal CS is applied after an LSB ‘1’ is input, the first and second switching elements 222′ and 224′ are turned off, and each of the first capacitor C_{C1}′ and the second capacitor C_{C2}′ has an average value (0.5 VDD) of electric charges charged by the charge sharing.

Next, when ‘0’ is input as a third bit, the second switching element 224′ is turned on, and the first switching element 222′ is turned off. Accordingly, the power supply voltage VDD is applied to the first capacitor C_{C1}′, such that the first capacitor C_{C1}′ is charged to a high level, and the second capacitor C_{C2}′ maintains a previous state. Unlike the embodiments of FIGS. 3 and 6, when the input data is ‘0’, the first capacitor C_{C1}′ is charged to a high level. Thereafter, the first capacitor C_{C1}′ and the second capacitor C_{C2}′ are each charged to an average value by the charge sharing signal CS.

Next, as ‘1’ is input as a second bit, the first switching element 222′ is turned on and the second switching element 224′ is turned off, and accordingly, a charging state of the first capacitor CC1′ is changed by the storage data stored in the storage unit 210. Thereafter, the first capacitor C_{C1}′ and the second capacitor C_{C2}′ are each charged to an average value by the charge sharing signal CS.

Next, as ‘1’ is input as an MSB, the first switching element 222′ is turned on and the second switching element 224′ is turned off, and accordingly, a charging state of the first capacitor C_{C1}′ is changed by the storage data stored in the storage unit 210. Thereafter, the first capacitor C_{C1}′ and the second capacitor C_{C2}′ are each charged to an average value by the charge sharing signal CS again, and the average value is determined as the final charge voltage Vcs,final.

Finally, in an output evaluation step, the inverted control signal /EV is applied to the second switching element 224′, the first switching element 222′ maintains a turn-off state, the holding signal HD applied to a holding switching element is blocked. Accordingly, a voltage of one terminal of the first capacitor C_{C1}′ increases to the power supply voltage level VDD, and a voltage of the other terminal of the first capacitor C_{C1}′, that is, the output terminal BLc, becomes VDD-Vcs,final (final charge voltage) by capacitor coupling.

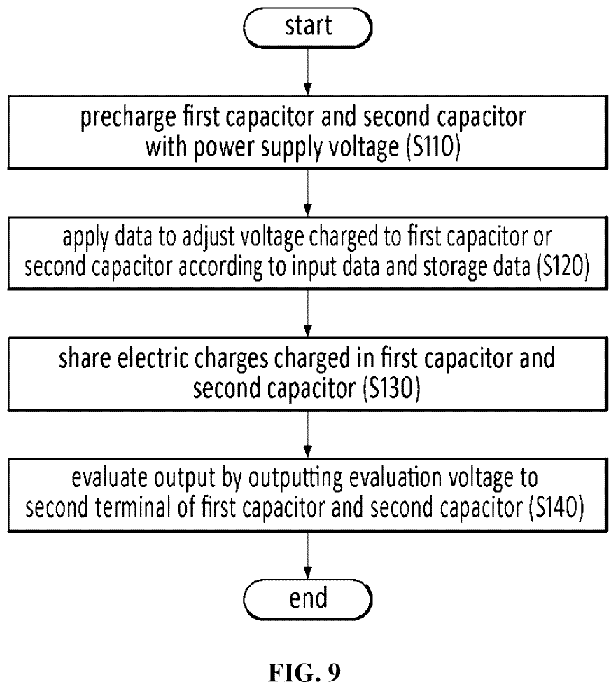

FIG. 9 is a flowchart illustrating an operating method of a memory device, according to an embodiment of the present disclosure.

First, a precharging step of charging a first capacitor and a second capacitor with a power supply voltage is performed (S110).

Next, a data application step is performed to adjust a voltage charged to the first capacitor or the second capacitor according to input data and storage data of the storage unit 210 (S120).

The data application step may be performed as in the embodiment of FIG. 3. That is, when a high-level bit of the input data is input, the storage data is applied to the first capacitor such that a charging voltage of the first capacitor is adjusted by the storage data, and when a low-level bit is input, the second capacitor is charged with the power supply voltage.

In contrast to this, the data application step may be performed as in the embodiment of FIG. 8. That is, when a high-level bit of the input data is input, the storage data is applied to the first capacitor such that a charging voltage of the first capacitor is adjusted by the storage data, and when a low-level bit is input, the first capacitor is charged with the power supply voltage.

Next, after the data application step, a charge sharing step is performed to share electric charges charged to the first capacitor and the second capacitor (S130).

Next, after the charge sharing step, the power supply voltage is applied to one terminal of the first capacitor and one terminal of the second capacitor such that an evaluation voltage is output to the other terminal of the first capacitor and the other terminal of the second capacitor (S140).

Because a level of the evaluation voltage changes depending on a result of multiplication of the input data and weight data, the multiplication of the input data and the weight data may be determined based on a level measurement result of the evaluation voltage.

A method according to an embodiment of the present disclosure may be performed in the form of a recording medium including instructions executable by a computer, such as a program module executed by a computer. A computer readable medium may be any available medium that may be accessed by a computer and includes both volatile and nonvolatile media, removable and non-removable media. Also, the computer readable medium may include a computer storage medium. A computer storage medium includes both volatile and nonvolatile media and removable and non-removable media implemented by any method or technology for storing information, such as computer readable instructions, data structures, program modules or other data.

In addition, although the method and system of the present disclosure are described with respect to specific embodiments, some or all of components or operations thereof may be implemented by using a computer system having a general-purpose hardware architecture.

The above description of the present disclosure is intended to be illustrative, and those skilled in the art will appreciate that the present disclosure may be readily modified in other specific forms without changing the technical idea or essential characteristics of the present disclosure. Therefore, the embodiments described above should be understood as illustrative in all respects and not limiting. For example, each component described in a single type may be implemented in a distributed manner, and likewise, components described in a distributed manner may be implemented in a combined form.

The scope of the present application is indicated by the claims described below rather than the detailed description above, and all changes or modified forms derived from the meaning, scope of the claims, and their equivalent concepts should be interpreted as being included in the scope of the present application.

What is claimed is:

1. A memory device comprising:
a plurality of memory cells, each being configured to perform in-memory computing;
a storage unit storing data; and
an operation circuit including a first capacitor and a second capacitor and configured to adjust a voltage charged to the first capacitor or a voltage charged to the second capacitor according to input data and storage data stored in the storage unit.

2. The memory device of claim 1, wherein
the operation circuit causes a first terminal of the first capacitor and a first terminal of the second capacitor to be selectively connected to each other by a switching element,
in a state where a second terminal of the first capacitor and a second terminal of the second capacitor are connected to an output terminal, the operation circuit precharges the first capacitor and the second capacitor to a high voltage,
when high-level input data is input, the operation circuit causes a charging state of the first capacitor to be changed according to the storage data,
when low-level input data is input, the operation circuit causes the second capacitor to be charged to a high voltage, and
the operation circuit causes the switching element to be turned on according to a charge sharing signal to connect the first capacitor to the second capacitor, such that an average value of charged voltages is charged to the first capacitor and the second capacitor.

3. The memory device of claim 1, further comprising:
a first switching element switched by a high-level bit among the input data in a multi-bit format, having a first terminal connected to one node of the storage unit, and having a second terminal connected to a first terminal of the first capacitor;
a second switching element switched by a low-level bit among the input data in the multi-bit format, having a first terminal connected to a power supply voltage, and having a second terminal connected to a first terminal of the second capacitor; and
a third switching element connected between the first terminal of the first capacitor and the first terminal of the second capacitor, and switched by a charge sharing signal,
wherein a second terminal of the first capacitor and a second terminal of the second capacitor are connected to an output terminal.

4. The memory device of claim 3, wherein
the operation circuit turns on the second switching element and the third switching element in a precharging step to charge the first capacitor and the second capacitor with a power supply voltage.

5. The memory device of claim 3, wherein,
when a high level bit is input, the operation circuit turns on the first switching element, turns off the second switching element, and turns off the third switching element in a data application mode, such that a charging voltage of the first capacitor is adjusted by the storage data,
when a low level bit is input, the operation circuit turns off the first switching element, turns on the second switching element, and turns off the third switching element in a data application mode to charge the second capacitor with the power supply voltage, and
after the data application mode ends, the operation circuit turns off the first switching element and the second switching element and turns on the third switching element by applying the charge sharing signal for a certain period of time in a charge sharing mode, such that electric charges charged in the first capacitor and the second capacitor are shared.

6. The memory device of claim 3, wherein,
the operation circuit turns off the first switching element, turns on the second switching element, and turns on the third switching element in an output evaluation mode, such that a power supply voltage is applied to the first terminal of the first capacitor and the first terminal of the second capacitor, and an evaluation voltage is output from the second terminal of the first capacitor and the second terminal of the second capacitor.

7. The memory device of claim 1, further comprising:
a first switching element that is switched by a high-level bit of the input data in a multi-bit format, has a first terminal connected to one node of the storage unit, and has a second terminal connected to a first terminal of the first capacitor;
a second switching element that is switched by a low-level bit of the input data in the multi-bit format, has a first terminal connected to a power supply voltage, and has a second terminal connected to the first terminal of the first capacitor; and
a third switching element connected between the first terminal of the first capacitor and a first terminal of the second capacitor and switched by a charge sharing signal,
wherein a second terminal of the first capacitor and a second terminal of the second capacitor are connected to an output terminal.

8. The memory device of claim 7, wherein
the operation circuit turns on the second switching element and the third switching element in a precharging step to charge the first capacitor and the second capacitor with a power supply voltage.

9. The memory device of claim 7, wherein,
when a high-level bit is input, the operation circuit turns on the first switching element, turns off the second switching element, and turns off the third switching element in a data application mode, such that a charging voltage of the first capacitor is adjusted by the storage data,
when a low-level bit is input, the operation circuit turns off the first switching element, turns on the second switching element, and turns off the third switching element in a data application mode to charge the first capacitor with the power supply voltage, and
after the data application mode ends, the operation circuit turns off the first switching element and the second switching element and turns on the third switching element by applying the charge sharing signal for a predetermined time in the charge sharing mode, such that the first capacitor and the second capacitor share charged electric charges.

10. The memory device of claim 3, wherein
the operation circuit turns off the first switching element, turns on the second switching element, and turns on the third switching element in an output evaluation mode, such that a power supply voltage is applied to the first terminal of the first capacitor and the first terminal of the second capacitor, and an evaluation voltage is output from the second terminal of the first capacitor and the second terminal of the second capacitor.

11. The memory device of claim 7, wherein
the operation circuit turns off the first switching element, turns on the second switching element, and turns on the third switching element in an output evaluation mode, such that a power supply voltage is applied to the first terminal of the first capacitor and the first terminal of the second capacitor, and an evaluation voltage is output from the second terminal of the first capacitor and the second terminal of the second capacitor.

12. The memory device of claim 3, wherein
the operation circuit repeatedly performs a data application mode and a charge sharing mode for each bit constituting the input data.

13. The memory device of claim 7, wherein
the operation circuit repeatedly performs a data application mode and a charge sharing mode for each bit constituting the input data.

14. An operating method of a memory device including a plurality of memory cells, each of which performs in-memory computing and includes a storage unit for storing data and an operation circuit adjusting a voltage charged to a first capacitor or a second capacitor according to input data and storage data stored in the storage unit, the operating method comprising:
precharging the first capacitor and the second capacitor with a power supply voltage; and
applying data to adjust a voltage charged to the first capacitor or the second capacitor according to the input data and the storage data.

15. The operating method of claim 14, wherein,
in the process of applying the data, when a high-level bit is input, the storage data is applied to the first capacitor such that a charging voltage of the first capacitor is adjusted by the storage data, and when a low-level bit is input, the second capacitor is charged with a power supply voltage.

16. The operating method of claim 14, wherein,
in the process of applying the data, when a high-level bit is input, the storage data is applied to the first capacitor such that a charging voltage of the first capacitor is adjusted by the storage data, and when a low-level bit is input, the first capacitor is charged with a power supply voltage.

17. The operating method of claim 14, further comprising:
sharing electric charges charged in the first capacitor and the second capacitor, after the process of applying the data.

18. The operating method of claim 17, further comprising:
evaluating an output by outputting an evaluation voltage to a second terminal of the first capacitor and a second terminal of the second capacitor, after applying the power supply voltage to a first terminal of the first capacitor and a first terminal of the second capacitor, after the process of sharing the electric charges.

19. The operating method of claim 17, wherein
the process of applying the data and the process of sharing the electric charges are repeatedly performed for each bit constituting the input data.
